(19) United States
(12) Patent Application Publication
(10) Pub. No.: US 2012/0042902 A1
(43) Pub. Date: Feb. 23, 2012

(54) CLEANING SHEET, TRANSFER MEMBER WITH CLEANING FUNCTION, CLEANING METHOD OF SUBSTRATE PROCESSING APPARATUS, AND SUBSTRATE PROCESSING APPARATUS

(75) Inventor: Daisuke Uenda, Suzuka-shi (JP)

(73) Assignee: NITTO DENKO CORPORATION, Ibaraki-shi, Osaka (JP)

(21) Appl. No.: 13/266,768

(22) PCT Filed: Apr. 13, 2010
(86) PCT No.: PCT/JP2010/056587

§ 371 Date: Oct. 27, 2011

(30) Foreign Application Priority Data
Apr. 30, 2009 (JP) 2009-110618

(51) Int. Cl. B08B 1/00; H01L 21/02

(52) U.S. Cl. 134/8; 15/209.1; 15/118

(57) ABSTRACT

Provided are a cleaning sheet and a transfer member provided with a cleaning function, which are excellent in foreign matter removing performance and transfer performance and which are capable of removing foreign matters each having a predetermined particle diameter particularly efficiently. The cleaning sheet of the present invention includes a cleaning layer substantially free of an adhesive ability, in which: the cleaning layer has an uneven portion having an average surface roughness Ra of 0.10 μm or more; and the cleaning layer has a 180° peeling adhesion of less than 0.20 N/10 mm, which is defined by JIS-Z-0237 with respect to a mirror surface of a silicon wafer. The transfer member provided with a cleaning function of the present invention includes a transfer member and the cleaning layer of the present invention provided on at least one surface of the transfer member.

### TECHNICAL FIELD

The present invention relates to a cleaning sheet and a transfer member provided with a cleaning function. More specifically, the present invention relates to a cleaning sheet and a transfer member provided with a cleaning function, which have excellent foreign matter removal performance and transfer performance and which can remove foreign matter each having a predetermined particle diameter with particularly high efficiency. The present invention also relates to a method of cleaning a substrate processing apparatus using such cleaning sheet and transfer member provided with a cleaning function, and to a substrate processing apparatus cleaned using such cleaning method.

### BACKGROUND ART

In various kinds of substrate processing apparatuses that are apt to be easily damaged by foreign matter, such as a production apparatus and an inspection apparatus of a semiconductor, a flat panel display, and a printed board, each transfer system and substrate are transferred while they are brought into contact with each other. In this case, when foreign matter adheres to the substrate and the transfer system, the subsequent substrates are contaminated one after another, and hence it is necessary to stop the apparatus periodically so as to clean the apparatus. As a result, there arise problems in that the operation rate of the processing apparatus decreases, and that a great amount of time and labor are required for cleaning the apparatus.

In order to solve such problems described above, a method of removing foreign matter adhering to a back surface of a substrate by transferring a plate-shaped member has been proposed (see Patent Literature 1). According to the method, it is not necessary to stop a substrate processing apparatus so as to clean the member, and the problem of decrease in the operation rate of the processing apparatus is solved. However, according to this method, foreign matter cannot be removed sufficiently.

On the other hand, a method of removing foreign matter adhering to a substrate processing apparatus by cleaning by transferring a substrate with an adherent material adhering thereto in the processing apparatus as a cleaning member has been proposed (see Patent Literature 2). This method has not only the advantage of the method described in Patent Literature 1, but also the excellent foreign matter removing performance. Therefore, this method solves the problem in that the operation rate of the processing apparatus decreases and the problem in that a great amount time and labor are required for cleaning the apparatus. However, according to the method described in Patent Literature 2, the adherent material and the apparatus are bonded to each other too strongly in a contact portion, so they may not come away from each other. Consequently, there arise problems in that the substrate may not be transferred securely, and that a transfer apparatus may be damaged.

In recent years, along with an increase in fineness of a semiconductor device, the adhesion of foreign matter to a wafer back surface as well as a wafer front surface has become a problem. This is because the foreign matter transfers from the wafer back surface to the wafer front surface during a cleaning step, which decreases a production yield. At present, a semiconductor element with a line width (design rule) of 65 nm is mainstream, and when a foreign matter of a size equal to or larger than the line width adheres to the semiconductor element, a defect such as open is liable to occur. In particular, foreign matter having a particle diameter of about 0.2 to 2.0 μm is a problem. However, any of the conventional technologies are insufficient for removing foreign matter each having a predetermined particle diameter with particularly high efficiency.

### CITATION LIST

### Patent Literature

[Patent Literature 1] JP 11-87458 A

[Patent Literature 2] JP 10-154686 A

### SUMMARY OF THE INVENTION

### Technical Problem

An object of the present invention is to provide a cleaning sheet and a transfer member provided with a cleaning function, which have excellent foreign matter removing performance and transfer performance, and which can remove foreign matters each having a predetermined particle diameter with particularly high efficiency. Another object of the present invention is to provide a method of cleaning a substrate processing apparatus using such cleaning sheet and transfer member provided with a cleaning function described above. Still another object of the present invention is to provide a substrate processing apparatus, which is cleaned using such cleaning method.

### Solution to Problem

A cleaning sheet of the present invention includes a cleaning layer substantially free of an adhesive ability,

in which: the cleaning layer has an uneven portion having an average surface roughness Ra of 0.10 μm or more; and

the cleaning layer has a 180° peeling adhesion of less than 0.20N/10 mm, which is defined by JIS-Z-0237 with respect to a mirror surface of a silicon wafer.

In a preferred embodiment, the cleaning sheet of the present invention includes a pressure-sensitive adhesive layer on one surface of the cleaning layer.

In a preferred embodiment, the cleaning sheet of the present invention includes a support on one surface of the cleaning layer.

In a preferred embodiment, the cleaning sheet of the present invention includes a pressure-sensitive adhesive layer on a surface of the support opposite to a surface on which the cleaning layer is provided.

According to another embodiment of the present invention, provided is a transfer member provided with a cleaning function. The transfer member provided with a cleaning function of the present invention includes a transfer member and the cleaning layer of the present invention provided on at least one surface of the transfer member.

In a preferred embodiment of the transfer member provided with a cleaning function according to the present invention, the cleaning layer is directly attached to the transfer member.

In a preferred embodiment of the transfer member provided with a cleaning function of the present invention, the cleaning layer is attached to the transfer member via a pressure-sensitive adhesive layer.

According to another embodiment of the present invention, provided is a method of cleaning a substrate processing apparatus. The method of cleaning a substrate processing apparatus of the present invention includes transferring the cleaning sheet of the present invention or the transfer member provided with a cleaning function of the present invention to an inside of a substrate processing apparatus.

According to another embodiment of the present invention, provided is a substrate processing apparatus. The substrate processing apparatus of the present invention is cleaned using the cleaning method of the present invention.

### ADVANTAGEOUS EFFECTS OF INVENTION

According to the present invention, the cleaning sheet and the transfer member provided with a cleaning function can be provided, which are excellent in foreign matter removing performance and transfer performance and which are capable of removing foreign matters each having a predetermined particle diameter particularly efficiently. According to the present invention, the method of cleaning a substrate processing apparatus using such cleaning sheet and transfer member provided with a cleaning function can also be provided. According to the present invention, the substrate processing apparatus which is cleaned using such cleaning method can also be provided.

These effects are expressed sufficiently by adopting the cleaning sheet including a cleaning layer substantially free of an adhesive ability as a cleaning sheet, designing an average surface roughness Ra of at least a part of the cleaning layer to be a predetermined value or more, and designing a peeling adhesion of the cleaning layer with respect to a mirror surface of a silicon wafer to be less than a predetermined value.

### BRIEF DESCRIPTION OF THE DRAWINGS

FIG. 1 is a schematic cross-sectional view of a cleaning sheet according to a preferred embodiment of the present invention.

FIG. 2 is a schematic cross-sectional view of a cleaning sheet according to another preferred embodiment of the present invention.

FIG. 3 is a schematic view of a wafer (3) used in an example seen from its top surface side.

FIG. 4 is a schematic view of a wafer (5) used in an example seen from its top surface side.

### REFERENCE CHARACTER LIST

10 cleaning layer
20 pressure-sensitive adhesive layer
30 protective film
40 support 40
100 cleaning sheet

### DESCRIPTION OF THE EMBODIMENTS

### A. Cleaning Sheet

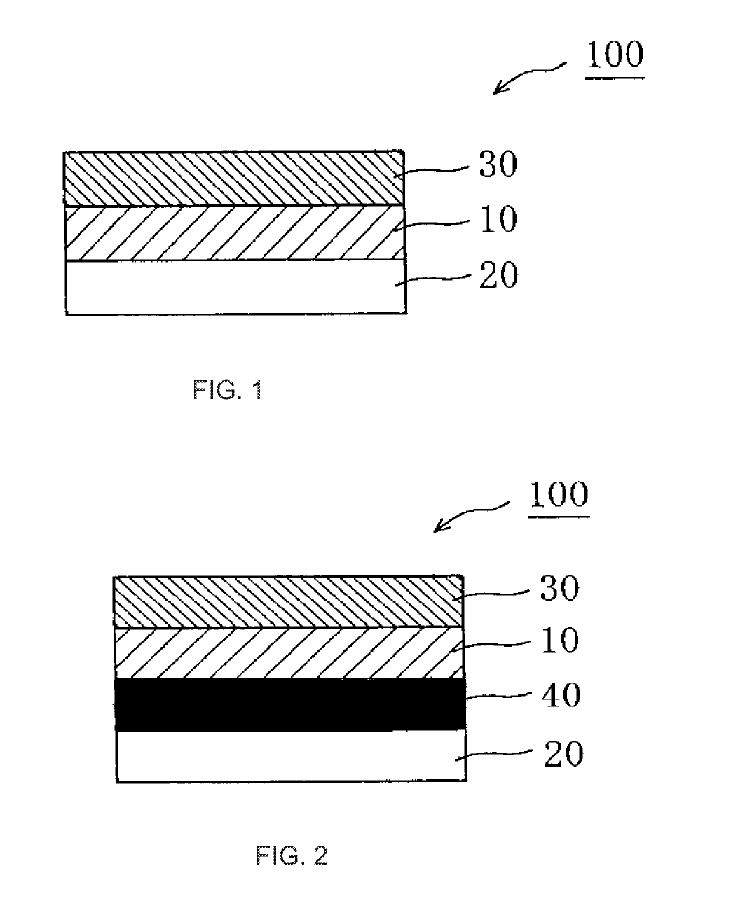

FIG. 1 is a schematic cross-sectional view of a cleaning sheet according to a preferred embodiment of the present invention. A cleaning sheet 100 in the figure includes a cleaning layer 10, a pressure-sensitive adhesive layer 20, and a protective film 30. The pressure-sensitive adhesive layer 20 and/or the protective film 30 may be omitted depending upon purposes. That is, the cleaning sheet may be constructed of the cleaning layer alone. FIG. 2 is a schematic cross-sectional view of a cleaning sheet according to another preferred embodiment of the present invention. Cleaning sheet 100 in the figure includes a cleaning layer 10, a pressure-sensitive adhesive layer 20, a protective film 30, and a support 40. The pressure-sensitive adhesive layer 20 and/or the protective film 30 may be omitted depending upon the purposes.

In the present invention, the cleaning layer is substantially free of an adhesive ability. More specifically, for example, a cleaning layer formed of an adherent material and a cleaning layer formed by fixing a pressure-sensitive adhesive tape are excluded from the cleaning layer of the present invention. When the cleaning sheet of the present invention includes a cleaning layer having an adhesive ability, the cleaning layer and an apparatus are bonded to each other in a contact portion too strongly, and hence, there is a possibility that the cleaning layer and the apparatus may not be separated. As a result, there may arise problems in that a substrate cannot be transferred with reliability and in that a transfer apparatus may be damaged.

The cleaning layer of the present invention has an uneven portion having an average surface roughness Ra of 0.10 μm or more. As the cleaning layer has such particular surface shape, a substrate can be transferred with reliability while foreign matters each having a predetermined particle diameter (typically, 0.2 to 2.0 μm) are removed very efficiently.

The average surface roughness Ra of the uneven portion of the cleaning layer of the present invention is preferably 0.10 to 1.0 μm, more preferably 0.10 to 0.80 μm, even more preferably 0.15 to 0.60 μm, particularly preferably 0.20 to 0.60 μm. When the average surface roughness Ra falls within such range, a substrate can be transferred with reliability while the foreign matter each having a predetermined particle diameter (typically, 0.2 to 2.0 μm) are further efficiently removed.

The average surface roughness Ra can be measured using a stylus surface roughness measuring instrument (Dectak 8, manufactured by Veeco). The stylus, made of diamond (curvature of a tip end portion is 2 μm), may be moved with a measurement speed of 1 μm/sec and in a measurement range of 2.0 mm.

Any suitable shape can be adopted as the unevenness shape of the uneven portion as long as the uneven portion has such an average surface roughness Ra. Specific examples of the unevenness shape include a groove shape, a stripe shape, a protrusion shape, a hollow (dimple) shape, and a rough surface shape like a sandpaper surface.

The elastic modulus in tension of the cleaning layer of the present invention is preferably 2,000 MPa or less, more preferably 0.5 to 2,000 MPa, even more preferably 1 to 1,000 MPa in a use temperature range of the cleaning layer. If the elastic modulus in tension falls within such range, a cleaning layer excellent in the balance between foreign matter removing performance and transfer performance is obtained. The elastic modulus in tension is measured in accordance with JIS K7127.

As described above, the cleaning layer of the present invention is substantially free of an adhesive ability. Specifically, the 180° peeling adhesion, which is defined by JIS-Z-0237 with respect to a mirror surface of a silicon wafer, is less than 0.20 N/10 mm, preferably 0.01 to 0.10 N/10 mm. When the 180° peeling adhesion falls within such range, the cleaning layer is substantially free of an adhesive ability, and the following problems can be solved. That is, the cleaning layer and an apparatus are bonded to each other in a contact portion too strongly to be separated from each other, which makes it impossible to transfer a substrate with reliability, damages a transfer apparatus, and renders dust removing property unsatisfactory.

The thickness of the cleaning layer of the present invention is preferably 0.1 to 100 μm, more preferably 0.5 to 50 μm, even more preferably 1 to 50 μm. When the thickness falls within such range, a cleaning layer excellent in the balance between foreign matter removing performance and transfer performance is obtained.

As a material for constructing the cleaning layer of the present invention, any suitable material can be adopted in accordance with the purpose and a method of forming unevenness. Specific examples of the material for constructing the cleaning layer include a heat-resistant resin and an energy ray curable resin. The material for constructing the cleaning layer is preferably a heat-resistant resin. By adopting the heat-resistant resin, even when the cleaning layer is used in apparatuses used at high temperatures, such as an ozone asher, a PVD apparatus, an oxidation diffusion furnace, an atmospheric pressure CVD apparatus, a reduced pressure CVD apparatus, and a plasma CVD apparatus, transfer defects and contamination in a processing apparatus during transfer can be avoided.

In the present invention, the material for constructing the cleaning layer may be used as it is to form the cleaning layer or may be dissolved in any suitable solvent to form the cleaning layer.

As the heat-resistant resin, a resin containing no material that contaminates a substrate processing apparatus is preferred. Examples of such resin include a heat-resistant resin used in a semiconductor production apparatus. Specific examples thereof include polyimide and a fluorocarbon resin. Polyimide is preferred.

Preferably, the polyimide can be obtained by imidizing polyamic acid. The polyamic acid can be obtained by reacting a tetracarboxylic dianhydride component and a diamine component in any suitable organic solvent in a substantially equimolar ratio.

Examples of the tetracarboxylic dianhydride component include 3,3′,4,4′-biphenyltetracarboxylic dianhydride, 2,2′,3,3′-biphenyltetracarboxylic dianhydride, 3,3′,4,4′-benzophenonetetracarboxylic dianhydride, 2,2′,3,3′-benzophenonetetracarboxylic dianhydride, 4,4′-oxydiphthalic dianhydride, 2,2-bis(2,3-dicarboxyphenyl)hexafluoropropane dianhydride, 2,2-bis(3,4-dicarboxyphenyl)hexafluoropropane dianhydride (6FDA), bis(2,3-dicarboxyphenyl)methane dianhydride, bis(3,4-dicarboxyphenyl)methane dianhydride, bis(2,3-dicarboxyphenyl)sulfone dianhydride, bis(3,4-dicarboxyphenyl)sulfone dianhydride, pyromellitic dianhydride, and ethylene glycol bistrimellitic dianhydride. Those may be used alone or in combination.

Examples of the diamine component include a diamine compound having at least two terminals each having an amine structure and having a polyether structure (hereinafter, sometimes referred to as PE diamine compound), an aliphatic diamine, and an aromatic diamine. The PE diamine compound is preferred for obtaining a polyimide resin with a low modulus of elasticity, which has high heat resistance and a low stress.

As the PE diamine compound, any suitable compound can be adopted as long as the compound has a polyether structure and at least two terminals each having an amine structure. Examples of the compound include a terminal diamine having a polypropylene glycol structure, a terminal diamine having a polyethylene glycol structure, a terminal diamine having a polytetramethylene glycol structure, and a terminal diamine having a plurality of those structures. More specifically, a PE diamine compound having at least two terminals each having an amine structure prepared from ethylene oxide, propylene oxide, polytetramethylene glycol, polyamine, or a mixture thereof is preferred.

Examples of the aliphatic diamine include ethylene diamine, hexamethylene diamine, 1,8-, 1,10-diaminodecane, 1,12-diaminododecane, 4,9-dioxa-1,12-diaminododecane, and 1,3-bis(3-aminopropyl)-1,1,3,3-tetramethyldisiloxane (α,ω-bisaminopropyltetramethyldisiloxane). The aliphatic diamine typically has a molecular weight of preferably 50 to 1,000,000, more preferably 100 to 30,000.

Examples of the aromatic diamine include 4,4′-diaminodiphenyl ether, 3,4′-diaminodiphenyl ether, 3,3′-diaminodiphenyl ether, m-phenylenediamine, p-phenylenediamine, 4,4′-diaminodiphenyl propane, 3,3′-diaminodiphenylmethane, 4,4′-diaminodiphenyl sulfide, 3,3′-diaminodiphenyl sulfide, 4,4′-diaminodiphenyl sulfone, 3,3′-diaminodiphenyl sulfone, 1,4-bis(4-aminophenoxy)benzene, 1,3-bis(4-aminophenoxy)benzene, 1,3-bis(3-aminophenoxy)benzene, 1,3-bis(4-aminophenoxy)-2,2-dimethylpropane, and 4,4′-diaminobenzophenone.

Examples of the organic solvent used for the reaction between the tetracarboxylic dianhydride and the diamine include N,N-dimethylacetamide, N-methyl-2-pyrrolidone, and N,N-dimethylformamide. In order to adjust the solubility of materials and the like, a non-polar solvent (e.g., toluene and xylene) may be used together.

The reaction temperature for the tetracarboxylic dianhydride and the diamine is preferably 40° C. or more, more preferably 50 to 150° C. At such reaction temperature, gelation can be prevented. As a result, a gel component does not remain in a reaction system, and hence clogging and the like during filtering are prevented, whereby foreign matter are removed from the reaction system easily. Further, a homogeneous reaction is realized at such reaction temperature, and hence, variation in characteristics of the resultant resin can be prevented.

The imidization of the polyamic acid is performed by heat treatment typically in an inactive atmosphere (typically, in a vacuum or nitrogen atmosphere). The heat treatment temperature is preferably 150° C. or more, more preferably 180 to 450° C. At such temperature, the volatile component in the resin can be removed substantially completely. Further, the oxidation and degradation of the resin can be prevented by the treatment in an inactive atmosphere.

The energy ray curable resin is typically a composition containing an adherent material, an energy ray curable material, and an energy ray curing initiator.

As the adherent material which may be contained in the energy ray curable resin, any suitable adherent material is adopted depending upon the purpose. The weight average molecular weight of the adherent material is preferably 500,000 to 1,000,000, more preferably 600,000 to 900,000. The adherent material may be mixed with an appropriate additive such as a cross-linking agent, a tackifier, a plasticizer, a filler, or an antioxidant. In one embodiment, a pressure-sensitive polymer is used as the adherent material, which may be contained in the energy ray curable resin. The pressure-sensitive polymer is used preferably in the case of using a nozzle method (described later) for forming unevenness in the cleaning layer. Typical examples of the pressure-sensitive polymer include acrylic polymers each containing, as a main monomer, an acrylic monomer such as (meth)acrylic acid and/or a (meth)acrylate. The acrylic polymers may be used alone or in combination. If required, the acrylic polymer itself may be provided with energy ray curing property by introducing an unsaturated double bond into molecules of the acrylic polymer. As a method of introducing an unsaturated double bond, there are given, for example, a method of copolymerizing an acrylic monomer with a compound having two or more unsaturated double bonds in the molecule, and a method of reacting a functional group of an acrylic polymer and a functional group of a compound having two or more unsaturated double bonds in the molecule.

In another embodiment, as the adherent material which may be contained in the energy ray curable resin, there may be used a rubber-based, acrylic, vinyl alkyl ether-based, silicone-based, polyester-based, polyamide-based, urethane-based, or styrene-diene block copolymer-based pressure-sensitive adhesive whose creep properties are improved by mixing a thermal melting resin having a melting point of about 200° C. or less (e.g., JP 56-61468 A, JP 61-174857 A, JP 63-17981A, JP 56-13040 A) or the like. Those materials may be used alone or in combination.

More specifically, the pressure-sensitive adhesive is preferably: a rubber-based pressure-sensitive adhesive having a natural rubber or various synthetic rubbers as a base polymer; or an acrylic pressure-sensitive adhesive having as a base polymer an acrylic copolymer formed of one kind or two or more kinds of acrylic acid-based alkyl esters each of which is an ester of acrylic acid, methacrylic acid, or the like containing an alkyl group having 20 or less carbon atoms, such as a methyl group, an ethyl group, a propyl group, a butyl group, an amyl group, a hexyl group, a heptyl group, a 2-ethylhexyl group, an isooctyl group, an isodecyl group, a dodecyl group, a lauryl group, a tridecyl group, a pentadecyl group, a hexadecyl group, a heptadecyl group, an octadecyl group, a nonadecyl group, or an eicosyl group.

As the acrylic copolymer, any suitable acrylic copolymer is used depending upon the purpose. The acrylic copolymer may have a cohesion, heat resistance, a cross-linking property, and the like, if required. Examples of the acrylic copolymer include acrylic copolymers each formed of two or more kinds of the following monomers: carboxyl group-containing monomers such as acrylic acid, methacrylic acid, carboxylethyl acrylate, carboxypentyl acrylate, icotanic acid, maleic acid, fumaric acid, and crotonic acid; acid anhydride monomers such as maleic anhydride and itaconic anhydride; hydroxyl group-containing monomers such as hydroxyethyl(meth)acrylate, hydroxyethyl(meth)acrylate, hydroxypropyl(meth)acrylate, hydroxybutyl(meth)acrylate, hydroxyhexyl(meth)acrylate, hydroxyoctyl(meth)acrylate, hydroxydecyl(meth)acrylate, hydroxylauryl(meth)acrylate, and (4-hydroxymethylcyclohexyl)-methyl methacrylate; sulfonic acid group-containing monomers such as styrenesulfonic acid, allylsulfonic acid, 2-(meth)acrylamide-2-methylpropanesulfonic acid, (meth)acrylamidepropanesulfonic acid, sulfopropyl(meth)acrylate, and (meth) acryloyloxynaphthalenesulfonic acid; (N-substituted)amide-based monomers such as (meth)acrylamide, N,N-dimethyl(meth)acrylamide, N-butyl(meth)acrylamide, N-methylol(meth)acrylamide, and N-methylolpropane(meth)acrylamide; alkylamino(meth)acrylate-based monomers such as aminoethyl(meth)acrylate, aminoethyl(meth)acrylate, N,N-dimethylaminoethyl(meth)acrylate, and t-butylaminoethyl(meth)acrylate; alkoxyalkyl(meth)acrylate-based monomers such as methoxyethyl(meth)acrylate and ethoxyethyl(meth)acrylate; maleimide-based monomers such as N-cyclohexylmaleimide, N-isopropylmaleimide, N-laurylmaleimide, and N-phenylmaleimide; itaconimide-based monomers such as N-methylitaconimide, N-ethylitaconimide, N-butylitaconimide, N-octylitaconimide, N-2-ethylhexylitaconimide, N-cyclohexylitaconimide, and N-laurylitaconimide; succinimide-based monomers such as N-(meth)acryloyloxymethylenesuccinimide, N-(meth)acryloyl-6-oxyhexamethylenesuccinimide, and N-(meth)acryloyl-8-oxyoctamethylenesuccinimide; vinyl-based monomers such as vinyl acetate, vinyl propionate, N-vinylpyrrolidone, methylvinylpyrrolidone, vinylpyridine, vinylpyperidone, vinylpyrimidine, vinylpiperazine, vinylpyrazine, vinylpyrrole, vinylimidazole, vinyloxazole, vinylmorpholine, N-vinylcarboxylic acid amides, styrene, α-methylstyrene, and N-vinylcaprolactam; cyanoacrylate monomers such as acrylonitrile and methacrylonitrile; epoxy group-containing acrylic monomers such as glycidyl(meth)acrylate; glycol-based acrylic ester monomers such as polyethylene glycol(meth)acrylate, polypropylene glycol(meth)acrylate, methoxyethylene glycol(meth)acrylate, and methoxypolypropylene glycol(meth)acrylate; acrylate-based monomers such as tetrahydrofurfuryl(meth)acrylate, fluoro(meth)acrylate, silicone(meth)acrylate, and 2-methoxyethyl acrylate; polyfunctional monomers such as hexanediol di(meth)acrylate, (poly)ethylene glycol di(meth)acrylate, (poly)propylene glycol di(meth)acrylate, neopentyl glycol di(meth)acrylate, pentaerythritol di(meth)acrylate, trimethylolpropane tri(meth)acrylate, pentaerytritol tri(meth)acrylate, dipentaerythritol hexa(meth)acrylate, epoxyacrylate, polyester acrylate, and urethane acrylate; and appropriate monomers such as isoprene, butadiene, isobutylene, and vinyl ether. The mixing ratios of those monomers or the like are appropriately set according to the purpose.

As the energy ray curable material, any suitable material can be adopted, which reacts with the adherent material with an energy ray (preferably, light, more preferably UV-ray), and is capable of functioning as a cross-linking point (branch point) for forming a three-dimensional network structure. A typical example of the energy ray curable material is a compound having one or more unsaturated double bonds in the molecule (hereinafter, referred to as polymerizable unsaturated compound). Preferably, the polymerizable unsaturated compound is non-volatile, and has a weight average molecular weight of 10,000 or less, more preferably 5,000 or less. With such molecular weight, the adherent material can form a three-dimensional network structure with good efficiency. Specific examples of the energy ray curable material include phenoxypolyethylene glycol(meth)acrylate, ε-caprolactone(meth)acrylate, polyethylene glycol di(meth)acrylate, polypropylene glycol di(meth)acrylate, trimethylolpropane tri(meth)acrylate, dipentaerythritol hexa(meth)acrylate, urethane(meth)acrylate, epoxy(meth)acrylate, oligoester(meth)acrylate, tetramethylolmethane tetra(meth)acrylate, pentaerythritol monohydroxypentaacrylate, 1,4-butylene glycol diacryalte, 1,6-hexanediol diacrylate, and polyethylene glycol diacrylate. Those may be used alone or in combination. The energy ray curable material is used in a ratio of preferably 0.1 to 50 parts by weight with respect to 100 parts by weight of the adherent material.

Further, an energy ray curable resin may be used as the energy ray curable material. Specific examples of the energy ray curable resin include ester(meth)acrylate, urethane(meth)acrylate, epoxy(meth)acrylate, melamine(meth)acrylate, and acrylic resin(meth)acrylate each of which has a (meth)acryloyl group at a molecular terminal, a thiol-ene resin and a photo cation polymerizable resin each of which has an allyl group at a molecular terminal, and polymers and oligomers each containing a photosensitive reactive group, including a polymer containing a cinnamoyl group such as polyvinyl cinnamate, a diazotized aminonovolac resin, and an acrylamide-based polymer. Further, examples of the polymer that reacts with energy ray include epoxidized polybutadiene, unsaturated polyester, polyglycidyl methacrylate, polyacrylamide, and polyvinylsiloxane. They may be used alone or in combination. The weight average molecular weight of the energy ray curable resin is preferably 500,000 to 1,000,000, more preferably 600,000 to 900,000.

As the energy ray curing initiator, any suitable curing initiator (polymerization initiator) can be adopted depending upon the purpose. For example, in the case of using heat as energy ray, a thermal polymerization initiator is used, and in the case of using light as energy ray, a photopolymerization initiator is used. Specific examples of the thermal polymerization initiator include benzoyl peroxide and azobisisobutyronitrile. Specific examples of the photopolymerization initiator include: benzoin ethers such as benzoin methyl ether, benzoin ethyl ether, benzoin isopropyl ether, and 2,2-dimethoxy-1,2-diphenylethan-1-one; substituted benzoin ethers such as anisole methyl ether; substituted acetophenones such as 2,2-diethoxyacetophenone, 2,2-dimethoxy-2-phenylacetophenone, and 1-hydroxy-cyclohexyl-phenyl ketone; ketals such as benzyl methyl ketal and acetophenone diethyl ketal; xanthones such as chlorothioxanthone, dodecylthioxanthone, and dimethylthioxanthone; benzophenones such as benzophenone and Michler's ketone; substituted alpha ketols such as 2-methyl-2-hydroxypropiophenone; aromatic sulfonyl chloride such as 2-naphthalene sulfonyl chloride; light-activated oxime such as 1-phenyl-1,1-propanedione-2-(o-ethoxycarbonyl)-oxime; benzoyl; dibenzyl; α-hydroxycyclohexylphenyl ketone; and 2-hydroxymethylphenylpropane. The ratio of the energy ray curing initiator to be used is preferably 0.1 to 10 parts by weight with respect to 100 parts by weight of the energy ray curable material.

The material for constructing the cleaning layer of the present invention can further contain any suitable additive depending upon the purpose. Specific examples of the additive include a surfactant, a plasticizer, an antioxidant, a conductivity providing agent, a UV-absorber, and a photostabilizer. By adjusting the kind and/or amount of the additive to be used, a cleaning layer having desired properties depending upon the purpose can be obtained.

The cleaning sheet of the present invention may include a support. The thickness of the support can be selected appropriately, and is preferably 500 μm or less, more preferably 1 to 300 μm, even more preferably 1 to 100 μm. The surface of the support may be subjected to conventional surface treatment, e.g., chemical or physical treatment such as chromic acid treatment, ozone exposure, flame exposure, high-pressure shock exposure, and ionized radiation treatment, or coating treatment with an undercoating agent (e.g., the adherent material) in order to enhance the adhesiveness with respect to an adjacent layer, retention property, and the like. The support may be a single layer or a multilayered body.

Any suitable support is adopted as the support depending upon the purpose. Examples of the support include an engineering plastic film and a super engineering plastic film. Specific examples of the engineering plastic and the super engineering plastic include polyimide, polyethylene, polyethylene terephthalate, acetyl cellulose, polycarbonate, polypropylene, and polyamide. Various physical properties such as a molecular weight can be appropriately selected depending upon the purpose. Further, a method of forming the support is appropriately selected depending upon the purpose.

The cleaning sheet of the present invention may include a pressure-sensitive adhesive layer. As a material for such pressure-sensitive adhesive layer, any suitable material can be adopted. For example, those which are made of acrylic or rubber-based general pressure-sensitive adhesives can be used. Of those, as an acrylic pressure-sensitive adhesive, an acrylic pressure-sensitive adhesive mainly containing an acrylic polymer having 10% by weight or less of a component of a weight average molecular weight of 100,000 or less is preferably used. The acrylic polymer can be synthesized by polymerizing a monomer mixture in which another copolymerizable monomer is added, if required, to a (meth)acrylic alkyl ester as a main monomer.

The pressure-sensitive adhesive layer of the present invention has a 180° peeling adhesion of preferably 0.01 to 10 N/10 mm, more preferably 0.05 to 5 N/10 mm, which is defined by JIS-Z-0237 of with respect to a mirror surface of a silicon wafer. When the adhesive ability is too strong, the support film may be torn during removal by peeling of the cleaning sheet from a substrate or the like.

The thickness of the pressure-sensitive adhesive layer of the present invention is preferably 1 to 100 μm, more preferably 5 to 50 μm.

The cleaning sheet of the present invention may have a protective film for protecting the cleaning layer and the support. The protective film is peeled in an appropriate stage. As the protective film, any suitable film is adopted depending upon the purpose. Examples of the film include: a plastic film made of polyolefin such as polyethylene, polypropylene, polybutene, polybutadiene, or polymethylpentene, polyvinyl chloride, a vinyl chloride copolymer, polyethylene terephthalate, polybutylene terephthalate, polyurethane, an ethylene vinyl acetate copolymer, an ionomer resin, an ethylene-(meth)acrylic acid copolymer, an ethylene-(meth)acrylic acid ester copolymer, polystyrene, or polycarbonate; a polyimide film; and a fluorocarbon resin film. The protective film may be subjected to release treatment with a releasing agent or the like depending upon the purpose. Examples of the releasing agent include a silicone type, a long-chain alkyl type, a fluorine type, an aliphatic amide type, and a silica type. The thickness of the protective film is preferably 1 to 100 μm. A method of forming the protective film is appropriately selected depending upon the purpose, and for example, the protective film can be formed by injection molding, extrusion molding, or blow molding.

Any suitable production method can be adopted as a method of producing the cleaning sheet of the present invention in the range in which the cleaning sheet of the present invention is obtained. As an example of a preferred production method, there is given a method involving forming unevenness on at least a part of the surface of any suitable substrate by laser processing and forming a cleaning layer on the surface of the substrate. That is, by providing unevenness on the surface of a substrate and forming a cleaning layer on the surface, an average surface roughness Ra of the surface of the cleaning layer is regulated to a predetermined level.

Any suitable substrate can be adopted as the substrate. Examples of the substrate include a semiconductor wafer (e.g., a silicon wafer), a substrate for a flat panel display such as an LCD or a PDP, a compact disk, and an MR head.

### B. Transfer Member Provided with Cleaning Function

A transfer member provided with a cleaning function of the present invention includes a transfer member and the cleaning layer of the present invention provided on at least one surface of the transfer member.

Any suitable transfer member can be adopted as the transfer member. Examples of the transfer member include a semiconductor wafer (e.g., a silicon wafer), a substrate for a flat panel display such as an LCD or a PDP, and a substrate for a compact disk or an MR head.

In the transfer member provided with a cleaning function of the present invention, the cleaning layer may be directly attached to the transfer member or may be attached to the transfer member via a pressure-sensitive adhesive layer.

As the pressure-sensitive adhesive layer, any suitable pressure-sensitive adhesive layer can be adopted. Preferably, the pressure-sensitive adhesive layer described in the item of A. cleaning sheet can be adopted.

### C. Cleaning Method

A cleaning method of the present invention is a method of cleaning a substrate processing apparatus, in which the cleaning sheet of the present invention or the transfer member provided with a cleaning function of the present invention is transferred to an inside of a substrate processing apparatus so as to be brought into contact with a site be cleaned in the apparatus, and thus, foreign matter adhering to the site to be cleaned are removed by cleaning easily with reliability.

The substrate processing apparatus to be cleaned by the cleaning method described above is not particularly limited. Specific examples of the substrate processing apparatus include, in addition to the apparatus described above herein, an exposure irradiation apparatus for forming a circuit, a resist applying apparatus, a sputtering apparatus, an ion injection apparatus, a dry etching apparatus, various kinds of production apparatuses and inspection apparatuses such as a wafer prober, and substrate processing apparatuses used under high temperature, such as an ozone asher, a resist coater, an oxidation diffusion furnace, an atmospheric CVD apparatus, a reduced pressure CVD apparatus, and a plasma CVD apparatus.

### D. Substrate Processing Apparatus

A substrate processing apparatus of the present invention is one cleaned using the cleaning method of the present invention. The substrate processing apparatus of the present invention is cleaned by transferring the cleaning sheet of the present invention or the transfer member provided with a cleaning function of the present invention to an inside of the substrate processing apparatus. Therefore, the substrate processing apparatus can be one in which foreign matters each having a predetermined particle diameter, in particular, a particle diameter of 0.2 to 2.0 μm is removed particularly efficiently.

### EXAMPLES

Hereinafter, the present invention is described more specifically with reference to examples. However, the present invention is not limited to the examples. It should be noted that, unless otherwise stated, part(s) and % in the examples are by weight (mass).

(1) Average Surface Roughness Ra

An average surface roughness Ra was measured using a stylus surface roughness measuring instrument (Dectak 8, manufactured by Veeco). The average surface roughness Ra was measured by moving a stylus made of diamond (curvature of a tip end portion is 2 μm) with a measurement speed of 1 μm/sec. and in a measurement range of 2.0 mm.

(2) Elastic Modulus in Tension

An elastic modulus in tension was measured in accordance with JIS K7127. Specifically, the elastic modulus in tension was measured with a dynamic viscoelastic measurement apparatus by forming a cleaning layer on a predetermined base material, and peeling the cleaning layer.

(3) 180° Peeling Adhesion

A cleaning layer was formed on a silicon wafer mirror surface, and the peeling adhesion thereof was measured in accordance with JIS-Z-0237.

(4) Method of Evaluating Cleaning Performance

Cleaning performance was evaluated by measuring the number of foreign matters of 0.200 μm or more on a silicon wafer mirror surface, using a foreign matter inspection apparatus (SFS6200 manufactured by KLA Tencor) (hereinafter, referred to as apparatus A). More specifically, the cleaning performance was evaluated by transferring a cleaning member to a liner film peeling apparatus (HR-300CW manufactured by Nitto Seiki Co., Ltd.) (hereinafter, referred to as apparatus B) for producing a cleaning sheet, and measuring the number of foreign matters before and after the transfer of the cleaning member. A specific method is as follows.

First, a new silicon wafer was automatically transferred to the apparatus B with a mirror surface thereof faced down in such a manner that the mirror surface was brought into contact with a transfer arm and a chuck table (face-down transfer). Then, the number of foreign matters adhering to the mirror surface was measured using the apparatus A (the number of foreign matters at this time is referred to as “foreign matter number 1”). After that, the cleaning member of the present invention was transferred to the apparatus B to perform cleaning treatment, and the new silicon wafer was transferred again so that the mirror surface thereof was faced down, and the number of foreign matters adhering to the mirror surface at this time was measured using the apparatus A (the number of foreign matters at this time is referred to as “foreign matter number 2”). A foreign matter removal ratio was calculated by the following equation as a parameter of the cleaning effect of the cleaning member.

Foreign matter removal ratio=[100−(Foreign matter number 2)/(Foreign matter number 1)×100]%

(5) Transferability

Transferability was evaluated by transferring a cleaning member onto the chuck table by the apparatus B, performing vacuum chucking, canceling the vacuum chucking, and thereafter, checking whether or not the cleaning member can be peeled from the chuck table with a lift pin.

### Example 1

200 parts of polyethylene glycol 200 dimethacrylate (NK ester 4G (trade name) manufactured by Shin-Nakamura Chemical Co., Ltd.), 3 parts of a polyisocyanate compound (COLONATE L (trade name) manufactured by Nippon Polyurethane Industry Co., Ltd.), and 3 parts of benzyl dimethyl ketal (IRGACURE 651 (trade name) as a photopolymerization initiator, manufactured by Ciba Specialty Chemicals Holding Inc.) were mixed homogeneously with respect to 100 parts of an acrylic polymer (weight average molecular weight: 700,000) obtained from a monomer mixture solution formed of 75 parts of 2-ethylhexyl acrylate, 20 parts of methyl acrylate, and 5 parts of acrylic acid, thereby preparing a UV-curable pressure-sensitive adhesive solution A.

On the other hand, to a 500-ml three-necked flask reactor equipped with a thermometer, a stirrer, a nitrogen introducing tube, and a reflux condenser tube, 73 parts of 2-ethylhexyl acrylate, 10 parts of n-butyl acrylate, 15 parts of N,N-dimethylacrylamide, 5 parts of acrylic acid, 0.15 parts of 2,2′-azobisisobutyronitrile as a polymerization initiator, and 100 parts of ethyl acetate were mixed and loaded so as to obtain a total amount of 200 g, the mixture was stirred while nitrogen gas was introduced to the reactor for about one hour, and the air inside the reactor was replaced by nitrogen.

After that, the temperature in the reactor was set to be 58° C., and this state was kept for about 4 hours to carry out polymerization, and thus, a pressure-sensitive adhesive polymer solution was obtained. Three parts of a polyisocyanate compound (COLONATE L (trade name) manufactured by Nippon Polyurethane Industry Co., Ltd.) were mixed homogeneously with 100 parts of the pressure-sensitive adhesive polymer solution to obtain a pressure-sensitive adhesive solution B.

The pressure-sensitive adhesive solution B was applied onto a release-treated surface of a separator one surface of which was made of a polypropylene film (thickness: 30 μm, width: 250 mm) so as to obtain a thickness of 7 μm after drying. A long polyester film (thickness: 25 μm, width: 250 mm) was laminated on the pressure-sensitive adhesive layer, and a UV-curable pressure-sensitive adhesive solution A was applied onto the film so as to obtain a thickness of 15 μm after drying to provide a pressure-sensitive adhesive layer as a cleaning layer. A release-treated surface of a protective film (protective film A) (thickness: 25 μm, width: 250 mm) made of a long-chain polyester film one surface of which was treated with a non-silicone releasing agent was attached to a surface of the pressure-sensitive adhesive layer to obtain a sheet (1).

The average surface roughness Ra of the protective film A was 0.12 μm.

The sheet (1) was irradiated with a UV-ray having a central wavelength of 365 nm in an accumulated light amount of 1,000 mJ/cm² to obtain a cleaning sheet (1) having a UV-cured cleaning layer.

The protective film A of the cleaning sheet (1) was peeled, and the 180° peeling adhesion (measured in accordance with JIS-Z-0237) with respect to a silicon wafer (mirror surface) was measured to be 0.05 N/10 mm. The tensile strength of the cleaning layer after UV-curing was 460 MPa.

The separator of the cleaning sheet (1) was peeled and the cleaning sheet was attached to a mirror surface of an 8-inch silicon wafer with a hand roller to produce a wafer with a back surface protective member (1).

Next, the protective film A of the wafer with a back surface protective member (1) was peeled to produce a transfer member provided with a cleaning function (1).

The average surface roughness Ra of the cleaning layer of the transfer member provided with a cleaning function (1) was 0.11 μm.

The number of foreign matters of 0.200 μm or more on the mirror surface of a new 8-inch silicon wafer was measured to be four by a laser type foreign matter measurement apparatus.

After the wafer was transferred with the mirror surface thereof faced down to the apparatus A, the number of foreign matters of 0.200 μm or more was measured by the laser type foreign matter measurement apparatus. The following results were obtained on a size basis: 5,552 in the range of 0.200 to 0.219 μm; 6,891 in the range of 0.219 to 0.301 μm; 4,203 in the range of 0.301 to 0.412 μm; 3,221 in the range of 0.412 to 0.566 μm; 3,205 in the range of 0.566 to 0.776 μm; 1,532 in the range of 0.776 to 1.06 μm; 698 in the range of 1.06 to 1.46 μm; 492 in the range of 1.46 to 1.60 μm; 925 in the range of 1.60 μm or more; and 26,719 (foreign matter number 1) in total.

When the transfer member provided with a cleaning function (1) was transferred ten times to the apparatus A to which the 26,719 foreign matters adhered, the transfer was performed without problems.

After that, a new 8-inch silicon wafer was transferred with the mirror surface thereof faced down, and the number of foreign matters of 0.200 μm or more was measured. The following results were obtained on a size basis: 2,234 in the range of 0.200 to 0.219 μm; 2,758 in the range of 0.219 to 0.301 μm; 1,688 in the range of 0.301 to 0.412 μm; 1,308 in the range of 0.412 to 0.566 μm; 1,309 in the range of 0.566 to 0.776 μm; 620 in the range of 0.776 to 1.06 μm; 282 in the range of 1.06 to 1.46 μm; 198 in the range of 1.46 to 1.60 μm; 371 in the range of 1.60 μm or more; and 10,768 (foreign matter number 2) in total.

The foreign matter removal ratio calculated based on the foreign matter number 1 and the foreign matter number 2 was 60% in total.

Table 1 summarizes the results.

### Example 2

In an atmosphere of a nitrogen stream, 14.8 g of polyether diamine (XTJ-510 manufactured by Suntechno Chemical Co.), 8.45 g of 4,4′-DPE (DDE), and 10.0 g of pyromellitic dianhydride (PMDA) were mixed with 133 g of N,N-dimethylacetamide (DAMc) at 70° C. and allowed to react to obtain a polyamic acid solution A.

After being cooled, the polyamic acid solution A was applied onto an etching surface of an 8-inch silicon wafer with a spin coater and dried at 90° C. for 20 minutes to obtain a transfer member with polyamic acid (2).

The transfer member with polyamic acid (2) was heat-treated at 300° C. for 2 hours in an atmosphere of nitrogen to form a polyimide coating film with a thickness of 30 μm, and thus, a transfer member with a cleaning function (2) was obtained.

The average surface roughness Ra of the cleaning layer of the transfer member provided with a cleaning function (2) was 0.54 μm.

The cleaning layer of the transfer member provided with a cleaning function (2) was peeled from the silicon wafer, and the 180° peeling adhesion (measured in accordance with JIS-Z-0237) with respect to the silicon wafer (mirror surface) was measured to be 0.03 N/10 mm.

The number of foreign matters of 0.200 μm or more on the mirror surface of a new 8-inch silicon wafer was measured to be five by a laser type foreign matter measurement apparatus.

After the wafer was transferred with the mirror surface thereof faced down to the apparatus A, the number of foreign matters of 0.200 μm or more was measured by the laser type foreign matter measurement apparatus. The following results were obtained on a size basis: 5,551 in the range of 0.200 to 0.219 μm; 6,890 in the range of 0.219 to 0.301 μm; 4,202 in the range of 0.301 to 0.412 μm; 3,220 in the range of 0.412 to 0.566 μm; 3,204 in the range of 0.566 to 0.776 μm; 1,531 in the range of 0.776 to 1.06 μm; 697 in the range of 1.06 to 1.46 μm; 491 in the range of 1.46 to 1.60 μm; 924 in the range of 1.60 μm or more; and 26,710 (foreign matter number 1) in total.

When the transfer member provided with a cleaning function (2) was transferred ten times to the apparatus A to which the 26,710 foreign matters adhered, the transfer was performed without problems.

After that, a new 8-inch silicon wafer was transferred with the mirror surface thereof faced down, and the number of foreign matters of 0.200 μm or more was measured. The following results were obtained on a size basis: 2,187 in the range of 0.200 to 0.219 μm; 2,708 in the range of 0.219 to 0.301 μm; 1,677 in the range of 0.301 to 0.412 μm; 1,273 in the range of 0.412 to 0.566 μm; 1,256 in the range of 0.566 to 0.776 μm; 602 in the range of 0.776 to 1.06 μm; 274 in the range of 1.06 to 1.46 μm; 194 in the range of 1.46 to 1.60 μm; 368 in the range of 1.60 μm or more; and 10,539 (foreign matter number 2) in total.

The foreign matter removal ratio calculated based on the foreign matter number 1 and the foreign matter number 2 was 61% in total.

Table 1 summarizes the results.

### Example 3

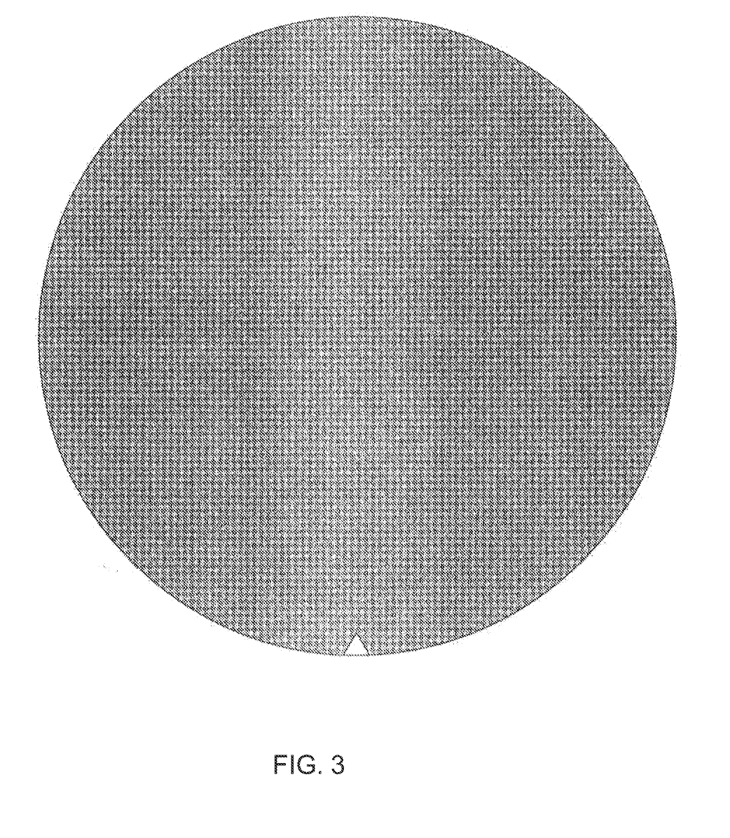

A laser mark for ID recognition defined under the SEMI specification was formed over the entire mirror surface of an 8-inch silicon wafer to obtain a wafer (3) as shown in FIG. 3. The polyamic acid solution A described in Example 2 was applied onto the mirror surface of the wafer (3) with a spin coater and dried at 120° C. for 10 minutes to obtain a transfer member provided with polyamic acid (3).

The transfer member with polyamic acid (3) was heat-treated at 300° C. for 2 hours in an atmosphere of nitrogen to form a polyimide coating film with a thickness of 8 μm, and thus, a transfer member with a cleaning function (3) was obtained.

The average surface roughness Ra of the cleaning layer of the transfer member provided with a cleaning function (3) was 0.34 μm.

The cleaning layer of the transfer member provided with a cleaning function (3) was peeled from the silicon wafer, and the 180° peeling adhesion (measured in accordance with JIS-Z-0237) with respect to the silicon wafer (mirror surface) was measured to be 0.02 N/10 mm.

The foreign matter of 0.200 μm or more on the mirror surface of a new 8-inch silicon wafer were measured to be two by a laser type foreign matter measurement apparatus.

After the wafer was transferred with the mirror surface thereof faced down to the apparatus A, the number of foreign matters of 0.200 μm or more was measured by the laser type foreign matter measurement apparatus. The following results were obtained on a size basis: 5,548 in the range of 0.200 to 0.219 μm; 6,887 in the range of 0.219 to 0.301 μm; 4,199 in the range of 0.301 to 0.412 μm; 3,217 in the range of 0.412 to 0.566 μm; 3,201 in the range of 0.566 to 0.776 μm; 1,528 in the range of 0.776 to 1.06 μm; 694 in the range of 1.06 to 1.46 μm; 488 in the range of 1.46 to 1.60 μm; 921 in the range of 1.60 μm or more; and 26,683 (foreign matter number 1) in total.

When the transfer member provided with a cleaning function (3) was transferred ten times to the apparatus A to which the 26,683 foreign matters adhered, the transfer was performed without problems.

After that, a new 8-inch silicon wafer was transferred with the mirror surface thereof faced down, and the number of foreign matters of 0.200 μm or more was measured. The following results were obtained on a size basis: 1,755 in the range of 0.200 to 0.219 μm; 2,184 in the range of 0.219 to 0.301 μm; 1,309 in the range of 0.301 to 0.412 μm; 1,003 in the range of 0.412 to 0.566 μm; 1,020 in the range of 0.566 to 0.776 μm; 477 in the range of 0.776 to 1.06 μm; 218 in the range of 1.06 to 1.46 μm; 155 in the range of 1.46 to 1.60 μm; 292 in the range of 1.60 μm or more; and 8,413 (foreign matter number 2) in total.

The foreign matter removal ratio calculated based on the foreign matter number 1 and the foreign matter number 2 was 68% in total.

Table 1 summarizes the results.

### Example 4

The pressure-sensitive adhesive solution A described in Example 1 was applied onto an etching surface of a 200 mm wafer with a spin coater and dried at 90° C. for 20 minutes to obtain a transfer member with a pressure-sensitive adhesive (4).

The transfer member with a pressure-sensitive adhesive (4) was irradiated with a UV-ray having a central wavelength of 365 nm in an accumulated light amount of 1,000 mJ/cm² in an atmosphere of nitrogen (oxygen concentration: 1,000 ppm) to obtain a UV-cured transfer member provided with a cleaning function (4).

The average surface roughness Ra of the cleaning layer of the transfer member provided with a cleaning function (4) was 0.42 μm.

The cleaning layer of the transfer member provided with a cleaning function (4) was peeled from the silicon wafer, and the 180° peeling adhesion (measured in accordance with JIS-Z-0237) with respect to the silicon wafer (mirror surface) was measured to be 0.03 N/10 mm.

The foreign matters of 0.200 μm or more on the mirror surface of a new 8-inch silicon wafer were measured to be five by a laser type foreign matter measurement apparatus.

After the wafer was transferred with the mirror surface thereof faced down to the apparatus A, the number of foreign matters of 0.200 μm or more was measured by the laser type foreign matter measurement apparatus. The following results were obtained on a size basis: 5,550 in the range of 0.200 to 0.219 μm; 6,889 in the range of 0.219 to 0.301 μm; 4,201 in the range of 0.301 to 0.412 μm; 3,219 in the range of 0.412 to 0.566 μm; 3,203 in the range of 0.566 to 0.776 μm; 1,530 in the range of 0.776 to 1.06 μm; 696 in the range of 1.06 to 1.46 μm; 490 in the range of 1.46 to 1.60 μm; 923 in the range of 1.60 μm or more; and 26,701 (foreign matter number 1) in total.

When the transfer member provided with a cleaning function (4) was transferred ten times to the apparatus A to which the 26,701 foreign matters adhered, the transfer was performed without problems.

After that, a new 8-inch silicon wafer was transferred with the mirror surface thereof faced down, and the number of foreign matters of 0.200 μm or more was measured. The following results were obtained on a size basis: 2,550 in the range of 0.200 to 0.219 μm; 3,100 in the range of 0.219 to 0.301 μm; 1,889 in the range of 0.301 to 0.412 μm; 1,408 in the range of 0.412 to 0.566 μm; 1,373 in the range of 0.566 to 0.776 μm; 619 in the range of 0.776 to 1.06 μm; 273 in the range of 1.06 to 1.46 μm; 190 in the range of 1.46 to 1.60 μm; 345 in the range of 1.60 μm or more; and 11,747 (foreign matter number 2) in total.

The foreign matter removal ratio calculated based on the foreign matter number 1 and the foreign matter number 2 was 56% in total.

Table 1 summarizes the results.

### Example 5

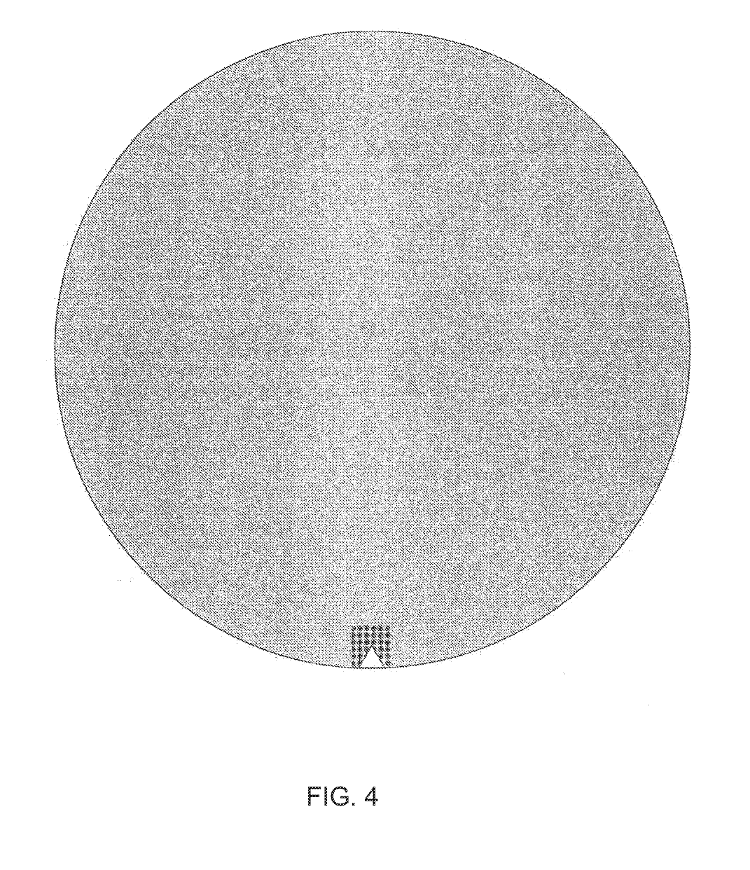

A laser mark measuring 3 mm by 3 mm for ID recognition defined under the SEMI specification was formed in a V-notch portion in the mirror surface of an 8-inch silicon wafer to obtain a wafer (5) as shown in FIG. 4. The polyamic acid solution A described in Example 2 was applied onto the mirror surface of the wafer (5) with a spin coater and dried at 120° C. for 10 minutes to obtain a transfer member provided with polyamic acid (5).

The transfer member with polyamic acid (5) was heat-treated at 300° C. for 2 hours in an atmosphere of nitrogen to form a polyimide coating film with a thickness of 8 μm, and thus, a transfer member with a cleaning function (5) was obtained.

The average surface roughness Ra of the laser mark-formed region shown in FIG. 4 of the cleaning layer of the transfer member provided with a cleaning function (5) was 0.38 μm. The average surface roughness Ra of the other regions was 0.005 μm.

The cleaning layer of the transfer member provided with a cleaning function (5) was peeled from the silicon wafer, and the 180° peeling adhesion (measured in accordance with JIS-Z-0237) with respect to the silicon wafer (mirror surface) was measured to be 0.03 N/10 mm.

The foreign matters of 0.200 μm or more on the mirror surface of a new 8-inch silicon wafer were measured to be two by a laser type foreign matter measurement apparatus.

After the wafer was transferred with the mirror surface thereof faced down to the apparatus A, the number of foreign matters of 0.200 μm or more was measured by the laser type foreign matter measurement apparatus. The following results were obtained on a size basis: 5,199 in the range of 0.200 to 0.219 μm; 6,493 in the range of 0.219 to 0.301 μm; 3,900 in the range of 0.301 to 0.412 μm; 2,987 in the range of 0.412 to 0.566 μm; 2,976 in the range of 0.566 to 0.776 μm; 1,378 in the range of 0.776 to 1.06 μm; 584 in the range of 1.06 to 1.46 μm; 405 in the range of 1.46 to 1.60 μm; 828 in the range of 1.60 μm or more; and 24,753 (foreign matter number 1) in total.

When the transfer member provided with a cleaning function (5) was transferred ten times to the apparatus A to which the 24,753 foreign matters adhered, the transfer was performed without problems.

After that, a new 8-inch silicon wafer was transferred with the mirror surface thereof faced down, and the number of foreign matters of 0.200 μm or more was measured. The following results were obtained on a size basis: 1,136 in the range of 0.200 to 0.219 μm; 1,487 in the range of 0.219 to 0.301 μm; 933 in the range of 0.301 to 0.412 μm; 712 in the range of 0.412 to 0.566 μm; 768 in the range of 0.566 to 0.776 μm; 372 in the range of 0.776 to 1.06 μm; 156 in the range of 1.06 to 1.46 μm; 114 in the range of 1.46 to 1.60 μm; 243 in the range of 1.60 μm or more; and 5,921 (foreign matter number 2) in total.

The foreign matter removal ratio calculated based on the foreign matter number 1 and the foreign matter number 2 was 76% in total.

Table 1 summarizes the results.

### Comparative Example 1

A transfer member provided with a cleaning function (C1) was obtained in the same way as in Example 1 except for using a protective film (protective film B) made of a long-chain polyester film one surface of which was treated with a silicone releasing agent, in place of the protective film A in Example 1.

The average surface roughness Ra of the protective film B was 0.009 μm.

The average surface roughness Ra of the transfer member provided with a cleaning function (C1) was 0.012 μm.

The transfer member provided with a cleaning function (C1) was transferred ten times to the apparatus A, and as a result, the transfer member was stuck to the apparatus A three times.

### Comparative Example 2

The polyamic acid solution A described in Example 2 was applied onto a mirror surface of an 8-inch silicon wafer with a spin coater and dried at 120° C. for 10 minutes to obtain a transfer member with polyamic acid (C2).

The transfer member with polyamic acid (C2) was heat-treated at 300° C. for 2 hours in an atmosphere of nitrogen to form a polyimide coating film with a thickness of 8 μm, and thus, a transfer member with a cleaning function (C2) was obtained.

The average surface roughness Ra of the transfer member provided with a cleaning function (C2) was 0.005 μm.

The transfer member provided with a cleaning function (C2) was transferred 100 times to the apparatus A, and as a result, the transfer member was stuck to the apparatus A five times.

TABLE 1

| | | | | | | | Foreign | |
|---|---|---|---|---|---|---|---|---|
| | Material | | | Ra of | Ra of | 180° | matter | |
| | for | Procedure | | uneven | smooth | peeling | removal | |
| | cleaning | for forming | Range of | portion | portion | adhesion | ratio | |
| | layer | unevenness | unevenness | (μm) | (μm) | (N/10 mm) | (%) | Transferability |
| Example 1 | Acrylic | Separator | Entire | 0.11 | — | 0.05 | 60 | Satisfactory |
| | | unevenness | surface | | | | | |
| | | use | | | | | | |
| Example 2 | Polyimide | Etching | Entire | 0.54 | — | 0.03 | 61 | Satisfactory |
| | | surface | surface | | | | | |
| | | coating | | | | | | |
| Example 3 | Polyimide | Entire | Entire | 0.34 | — | 0.02 | 68 | Satisfactory |
| | | surface | surface | | | | | |
| | | laser | | | | | | |
| Example 4 | Acrylic | Etching | Entire | 0.42 | — | 0.03 | 56 | Satisfactory |
| | | surface | surface | | | | | |
| | | coating | | | | | | |
| Example 5 | Polyimide | Partly | Part | 0.38 | 0.005 | 0.03 | 76 | Satisfactory |
| | | laser | | | | | | |
| Comparative | Acrylic | Absent | Absent | — | 0.012 | — | — | Unsatisfactory |
| Example 1 | | | | | | | | |
| Comparative | Polyimide | Absent | Absent | — | 0.005 | — | — | Unsatisfactory |
| Example 2 | | | | | | | | |

### INDUSTRIAL APPLICABILITY

The cleaning sheet and the transfer member provided with a cleaning function of the present invention are each used preferably for cleaning of a substrate processing apparatus such as various kinds of production apparatuses and inspection apparatuses.

1. A cleaning sheet, comprising a cleaning layer substantially free of an adhesive ability,
wherein: the cleaning layer has an uneven portion having an average surface roughness Ra of 0.10 μm or more; and
the cleaning layer has a 180° peeling adhesion of less than 0.20 N/10 mm, which is defined by JIS-Z-0237 with respect to a mirror surface of a silicon wafer.

2. A cleaning sheet according to claim 1, wherein the cleaning sheet comprises a pressure-sensitive adhesive layer on one surface of the cleaning layer.

3. A cleaning sheet according to claim 1, wherein the cleaning sheet comprises a support on one surface of the cleaning layer.

4. A cleaning sheet according to claim 3, wherein the cleaning sheet comprises a pressure-sensitive adhesive layer on a surface of the support opposite to a surface on which the cleaning layer is provided.

5. A transfer member provided with a cleaning function, comprising a transfer member, and the cleaning layer according to claim 1, the cleaning layer being provided on at least one surface of the transfer member.

6. A transfer member provided with a cleaning function according to claim 5, wherein the cleaning layer is directly attached to the transfer member.

7. A transfer member provided with a cleaning function according to claim 5, wherein the cleaning layer is attached to the transfer member via a pressure-sensitive adhesive layer.

8. A method of cleaning a substrate processing apparatus, comprising:
transferring a cleaning sheet comprising a cleaning layer substantially free of an adhesive ability, the cleaning layer having an uneven portion having an average surface roughness Ra of 0.10 μm or more and a 180° peeling adhesion of less than 0.20 N/10 mm as defined by JIS-Z-0237 with respect to a mirror surface of a silicon wafer to an inside of a substrate processing apparatus.

9. A substrate processing apparatus, which is cleaned using the cleaning method according to claim 8.
